(19) United States
(12) Patent Application Publication
(10) Pub. No.: US 2014/0246082 A1
(43) Pub. Date: Sep. 4, 2014

(54) STACKED BODY FOR MANUFACTURING COMPOUND SEMICONDUCTOR SOLAR BATTERY, COMPOUND SEMICONDUCTOR SOLAR BATTERY, AND METHOD FOR MANUFACTURING COMPOUND SEMICONDUCTOR SOLAR BATTERY

(71) Applicants: Hiroyuki Juso, Osaka-shi (JP); Naoki Takahashi, Osaka-shi (JP)

(72) Inventors: Hiroyuki Juso, Osaka-shi (JP); Naoki Takahashi, Osaka-shi (JP)

(73) Assignee: SHARP KABUSHIKI KAISHA, Osaka-shi, Osaka (JP)

(21) Appl. No.: 14/348,442

(22) PCT Filed: Aug. 29, 2012
(86) PCT No.: PCT/JP2012/071823

§ 371 Date: Mar. 28, 2014

(30) Foreign Application Priority Data
Sep. 30, 2011 (JP) 2011-217190

(51) Int. Cl. H01L 31/0725; H01L 31/18

(52) U.S. Cl. CPC H01L 31/0725; H01L 31/184
USPC 136/255; 438/93

(57) ABSTRACT

Disclosed is a stacked body for manufacturing a compound semiconductor solar battery, wherein a first etching stop layer (103) and a semiconductor stacked body (10) including at least one pn junction are arranged in this order on a semiconductor substrate (100), the semiconductor stacked body (10) has a contact layer (104) at a position in contact with the first etching stop layer, and the first etching stop layer (103) and the contact layer (104) contain a group V element of the same type.

### TECHNICAL FIELD

The present invention relates to a stacked body for manufacturing a compound semiconductor solar battery, a compound semiconductor solar battery, and a method for manufacturing the compound semiconductor solar battery.

### BACKGROUND ART

A conventional method for increasing efficiency of a compound semiconductor solar battery (increasing photoelectric conversion efficiency) is to grow compound semiconductor layers having a lattice constant similar to that of a semiconductor substrate on the semiconductor substrate to form a plurality of compound semiconductor photoelectric conversion cells, thus obtaining a compound semiconductor solar battery having good crystallinity.

However, compound semiconductor solar batteries including compound semiconductor photoelectric conversion cells having a lattice constant similar to that of Si, Ge, GaAs, InP or the like which forms a main semiconductor substrate for growing compound semiconductor layers and further having a suitable forbidden band width have been limited to an InGaPGaAs compound semiconductor solar battery including a GaAs substrate, an InGaPInGaAsGe compound semiconductor solar battery including a Ge substrate, and so on.

One method for achieving higher efficiency than that of these compound semiconductor solar batteries is to dispose a compound semiconductor photoelectric conversion cell having a forbidden band width of 1 eV as a third compound semiconductor photoelectric conversion cell in an InGaPGaAs solar battery.

Unfortunately, there are no appropriate compound semiconductors having a lattice constant similar to that of GaAs and a forbidden band width of approximately 1 eV. Although InGaAs having a lattice constant mismatched from that of GaAs by approximately 2.3% has a forbidden band width of approximately 1 eV, if InGaAs is used as a third compound semiconductor photoelectric conversion cell in an InGaPGaAs compound semiconductor solar battery, a lattice-matched semiconductor is grown after a lattice-mismatched semiconductor is grown on a GaAs substrate, which may cause deterioration of crystallinity of the lattice-matched semiconductor, resulting in performance degradation of the entire compound semiconductor solar battery.

As such, studies have been done on a method for growing compound semiconductor layers having a lattice constant similar to that of a semiconductor substrate on the semiconductor substrate such that a light-receiving surface of a compound semiconductor solar battery is on the semiconductor substrate side, and then growing compound semiconductor layers having a lattice constant different from that of the semiconductor substrate with a buffer layer interposed therebetween (see NPD 1: J. F. Geisz et al., “Inverted GaInPGaAsInGaAs triple-junction solar cells with low-stress metamorphic bottom junctions”, 33th IEEE Photovoltaic Specialists Conference, 2008, for example).

That is, a compound semiconductor solar battery is usually formed by growing compound semiconductor layers such that a light-receiving surface is positioned opposite to a semiconductor substrate serving as a growth substrate (i.e., formed such that the light-receiving surface is positioned in a growth direction of the compound semiconductor layers). By growing compound semiconductor layers such that a light-receiving surface is on the semiconductor substrate side, however, good crystallinity is obtained in a compound semiconductor photoelectric conversion cell including the compound semiconductor layers having a lattice constant similar to that of the semiconductor substrate, and the characteristics of a compound semiconductor photoelectric conversion cell including lattice-mismatched compound semiconductor layers having a lattice constant different from that of the semiconductor substrate are also obtained, thereby achieving a highly efficient compound semiconductor solar battery.

Furthermore, the inventors of the present invention develops the technique of manufacturing a compound semiconductor solar battery of higher efficiency by controlling a ratio of a difference in lattice constant between a bottom cell and a buffer layer that are adjacent to each other, in the aforementioned method for growing compound semiconductor layers such that a light-receiving surface of a semiconductor substrate serving as a growth substrate is on the semiconductor substrate side (PTD 1: Japanese Patent Laying-Open No. 2010-182951).

### CITATION LIST

### Patent Document

PTD 1: Japanese Patent Laying-Open No. 2010-182951

### Non Patent Document

NPD 1: J. F. Geisz et al., “Inverted GaInPGaAsInGaAs triple-junction solar cells with low-stress metamorphic bottom junctions”, 33th IEEE Photovoltaic Specialists Conference, 2008

### SUMMARY OF INVENTION

### Technical Problem

However, a compound semiconductor solar battery of higher performance is still desired and further technological development is required. In view of the above circumstances, an object of the present invention is to provide a stacked body for manufacturing a compound semiconductor solar battery of excellent performance, a compound semiconductor solar battery, and a method for manufacturing the compound semiconductor solar battery.

### Solution to Problem

Specifically, a first manner of the present invention is directed to a stacked body for manufacturing a compound semiconductor solar battery, wherein a first etching stop layer and a semiconductor stacked body including at least one pn junction are arranged in this order on a semiconductor substrate, the semiconductor stacked body has a contact layer at a position in contact with the first etching stop layer, and the first etching stop layer and the contact layer contain a group V element of the same type.

A second manner of the present invention is directed to a stacked body for manufacturing a compound semiconductor solar battery, wherein a first etching stop layer and a semiconductor stacked body including at least one pn junction are arranged in this order on a semiconductor substrate, the semiconductor stacked body has a contact layer at a position in contact with the first etching stop layer, each of the first etching stop layer and the contact layer contains a group V element, and the group V element contained in the first etching stop layer and the group V element contained in the contact layer are of the same type.

Preferably, in the stacked body for manufacturing a compound semiconductor solar battery, the first etching stop layer and the semiconductor stacked body are epitaxially grown layers.

Preferably, in the stacked body for manufacturing a compound semiconductor solar battery, the first etching stop layer is an AlAs layer.

Preferably, in the stacked body for manufacturing a compound semiconductor solar battery, between the semiconductor substrate and the first etching stop layer, a second etching stop layer and a third etching stop layer are arranged in this order from the first etching stop layer side.

Preferably, in the stacked body for manufacturing a compound semiconductor solar battery, the second etching stop layer and the third etching stop layer are epitaxially grown layers.

Preferably, in the stacked body for manufacturing a compound semiconductor solar battery, the second etching stop layer is a GaAs layer and the third etching stop layer is an InGaP layer.

Preferably, in the stacked body for manufacturing a compound semiconductor solar battery, the contact layer is a GaAs layer.

A third manner of the present invention is directed to a compound semiconductor solar battery manufactured using the aforementioned stacked body for manufacturing a compound semiconductor solar battery, the compound semiconductor solar battery including the semiconductor stacked body.

Preferably, the compound semiconductor solar battery is formed by etching the first etching stop layer that is in contact with the contact layer of the semiconductor stacked body.

A fourth manner of the present invention is directed to a method for manufacturing a compound semiconductor solar battery, including the steps of: forming a first etching stop layer on a semiconductor substrate; forming, on the first etching stop layer, a semiconductor stacked body including at least one pn junction; arranging a support substrate on a compound semiconductor layer formed at a position farthest from the first etching stop layer of the semiconductor stacked body; and etching the first etching stop layer, wherein the step of forming a semiconductor stacked body includes the step of forming a contact layer at a position in contact with the first etching stop layer, and the first etching stop layer and the contact layer contain a group V element of the same type.

A fifth manner of the present invention is directed to a method for manufacturing a compound semiconductor solar battery, including the steps of: forming a first etching stop layer on a semiconductor substrate; forming, on the first etching stop layer, a semiconductor stacked body including at least one pn junction; arranging a support substrate on a compound semiconductor layer formed at a position farthest from the first etching stop layer of the semiconductor stacked body; and etching the first etching stop layer, wherein the step of forming a semiconductor stacked body includes the step of forming a contact layer at a position in contact with the first etching stop layer, each of the first etching stop layer and the contact layer contains a group V element, and the group V element contained in the first etching stop layer and the group V element contained in the contact layer are of the same type.

Preferably, in the method for manufacturing a compound semiconductor solar battery, the step of forming a first etching stop layer includes the steps of forming a third etching stop layer on the semiconductor substrate; forming a second etching stop layer on the third etching stop layer; and forming the first etching stop layer on the second etching stop layer.

Preferably, in the method for manufacturing a compound semiconductor solar battery, the step of etching the third etching stop layer and the step of etching the second etching stop layer are included before the step of etching the first etching stop layer.

Preferably, in the method for manufacturing a compound semiconductor solar battery, at least any one of acids selected from the group of hydrofluoric acid, citric acid and hydrochloric acid is used in at least one of the step of etching the first etching stop layer, the step of etching the second etching stop layer and the step of etching the third etching stop layer.

### Advantageous Effects of Invention

According to the present invention, there can be provided a stacked body for manufacturing a compound semiconductor solar battery of excellent performance, a compound semiconductor solar battery, and a method for manufacturing the compound semiconductor solar battery.

### BRIEF DESCRIPTION OF DRAWINGS

FIG. 1 is a schematic cross-sectional structure diagram of an example of a stacked body for manufacturing a compound semiconductor solar battery according to a first embodiment.

FIG. 2 is a schematic cross-sectional structure diagram illustrating part of a manufacturing process of an example of a method for manufacturing the compound semiconductor solar battery using the stacked body for manufacturing the compound semiconductor solar battery shown in FIG. 1.

FIG. 3 is a schematic cross-sectional structure diagram illustrating another part of the manufacturing process of the example of the method for manufacturing the compound semiconductor solar battery.

FIG. 4 is a schematic cross-sectional structure diagram illustrating yet another part of the manufacturing process of the example of the method for manufacturing the compound semiconductor solar battery.

FIG. 5 is a schematic cross-sectional structure diagram illustrating yet another part of the manufacturing process of the example of the method for manufacturing the compound semiconductor solar battery.

FIG. 6 is a schematic cross-sectional structure diagram illustrating yet another part of the manufacturing process of the example of the method for manufacturing the compound semiconductor solar battery.

FIG. 7 is a schematic cross-sectional structure diagram illustrating yet another part of the manufacturing process of the example of the method for manufacturing the compound semiconductor solar battery.

FIG. 8 is a schematic cross-sectional structure diagram of an example of the manufactured compound semiconductor solar battery.

FIG. 9 is a schematic cross-sectional structure diagram of an example of a stacked body for manufacturing a compound semiconductor solar battery according to a second embodiment.

FIG. 10 is a schematic cross-sectional structure diagram illustrating part of a manufacturing process of an example of a method for manufacturing the compound semiconductor solar battery using the stacked body for manufacturing the compound semiconductor solar battery shown in FIG. 9.

FIG. 11 is a schematic cross-sectional structure diagram illustrating another part of the manufacturing process of the example of the method for manufacturing the compound semiconductor solar battery.

FIG. 12 is a schematic cross-sectional structure diagram of a stacked body for manufacturing a compound semiconductor solar battery, which is used to manufacture a compound semiconductor solar battery in Example 1.

FIG. 13 is a schematic cross-sectional structure diagram of the compound semiconductor solar battery in Example 1.

FIG. 14 is a schematic cross-sectional structure diagram of a stacked body for manufacturing a compound semiconductor solar battery, which is used to manufacture a compound semiconductor solar battery in Comparative Example 1.

FIG. 15 is a graph showing current-voltage characteristics of the compound semiconductor solar battery in each of Example 1 and Comparative Example 1.

### DESCRIPTION OF EMBODIMENTS

The inventors of the present invention have further advanced their study of the technique disclosed in PTD 1, and have found that a compound semiconductor solar battery which does not bring desired conversion efficiency may be manufactured in some cases, and thus, the yield of the compound semiconductor solar battery tends to be low. As such, the inventors of the present invention have advanced their earnest study of a cause of this low yield, and have found out that the following is the cause.

Specifically, according to the technique disclosed in PTD 1, an etching stop layer made of InGaP is formed on a semiconductor substrate serving as a growth substrate, and a contact layer constituting a compound semiconductor solar battery is formed to be in contact with the etching stop layer. When the etching stop layer is epitaxially grown on the semiconductor substrate, a mixed gas containing a PH₃ (phosphine) gas is introduced into an MOCVD (Metal Organic Chemical Vapor Deposition) device having the semiconductor substrate arranged therein. When the contact layer is epitaxially grown on the etching stop layer, a mixed gas containing an AsH₃ (arsine) gas is introduced into this MOCVD device.

Therefore, it is necessary to do switching from the mixed gas containing the PH₃ gas to the mixed gas containing the AsH₃ gas in the MOCVD device. However, it has turned out that at the time of this switching, there exists a state in which both gases are present in a mixed manner, and thus, an unintended modified layer is formed at an interface between the etching stop layer and the contact layer. Such a modified layer is considered as a mixed crystal region in which compositions of a group III element such as In and Ga and a group V element such as As and P change rapidly. Presence of this modified layer at the interface of the contact layer inhibits contact between the contact layer and a metal layer formed on the contact layer, and thus, serial resistance in the compound semiconductor solar battery increases, and as a result, the desired conversion efficiency cannot be obtained.

As such, the inventors of the present invention have advanced their earnest study by focusing attention on suppressing formation of the aforementioned modified layer, and have completed the present invention.

Embodiments of the present invention will be described hereinafter. It is noted that the same or corresponding parts have the same reference marks allotted in the drawings of the present invention. In the present specification, when a composition ratio of elements constituting a compound is not described in a chemical formula of the compound and their compositions are not particularly mentioned, the composition ratio shall not be particularly limited but can be set as appropriate.

### First Embodiment

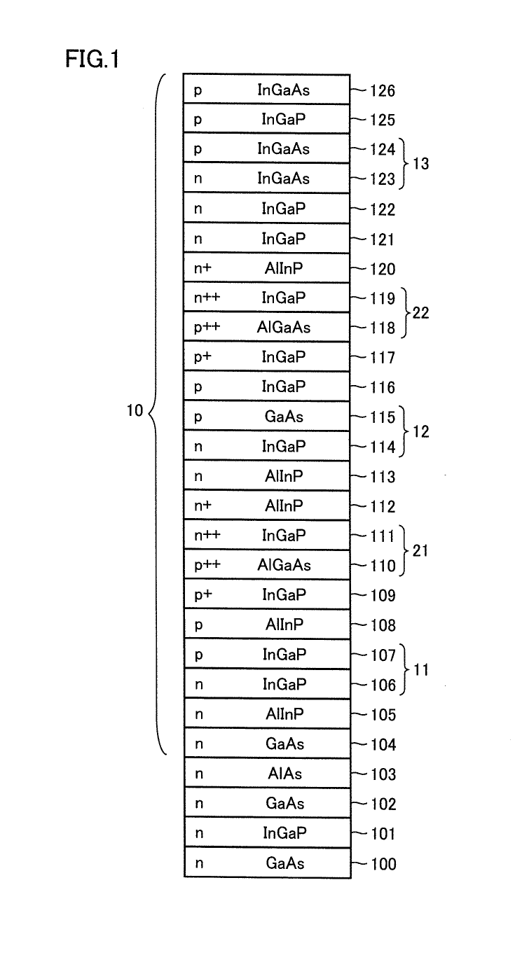

FIG. 1 is a schematic cross-sectional structure diagram of an example of a stacked body for manufacturing a compound semiconductor solar battery according to a first embodiment. In this stacked body for manufacturing the compound semiconductor solar battery, a third etching stop layer 101 (e.g., 0.05 μm to 0.3 μm thick) made of n type InGaP, a second etching stop layer 102 (e.g., 0.3 μm to 0.7 μm thick) made of n type GaAs, a first etching stop layer 103 (e.g., 0.01 μm to 0.1 μm thick) made of n type AlAs, and a semiconductor stacked body 10 are continuously arranged in this order on a semiconductor substrate 100 (e.g., having a diameter of 100 mm) made of n type GaAs.

Semiconductor stacked body 10 is formed by stacking, from the side in contact with first etching stop layer 103, a contact layer 104 (e.g., 0.3 μm to 1.0 μm thick) made of n type GaAs, a window layer 105 (e.g., 0.01 μm to 0.05 μm thick) made of n type AlInP, a top cell 11 (e.g., 0.5 μm to 1.0 μm thick), a BSF (Back Surface Field) layer 108 (e.g., 0.03 μm to 0.1 μm thick) made of p type AlInP, a p+InGaP layer 109 (e.g., 0.015 μm to 0.04 μm thick), a tunnel junction layer 21, an n+AlInP layer 112 (e.g., 0.015 μm to 0.04 μm thick), a window layer 113 (e.g., 0.01 μm to 0.05 μm thick) made of n type AlInP, a middle cell 12 (e.g., 2.0 μm to 5.0 μm thick), a BSF layer 116 (e.g., 0.05 μm to 0.2 μm thick) made of p type InGaP, a p+InGaP layer 117 (e.g., 0.02 μm to 0.07 μm thick), a tunnel junction layer 22 (e.g., 0.05 μm to 0.2 μm thick), an n+AlInP layer 120 (e.g., 0.015 μm to 0.04 μm thick), a buffer layer 121 (e.g., 2.0 μm to 3.0 μm thick) made of n type InGaP, a window layer 122 (e.g., 0.05 μm to 0.15 μm thick) made of n type InGaP, a bottom cell 13 (e.g., 2.0 μm to 5.0 μm thick), a BSF layer 125 (e.g., 0.1 μm to 0.3 μm thick) made of p type InGaP, and a contact layer 126 (e.g., 0.3 μm to 0.8 μm thick) made of p type InGaAs in this order.

Top cell 11 is a joined body of an emitter layer 106 (e.g., 0.03 μm to 0.1 μm thick) made of n type InGaP, which is stacked on window layer 105, and a base layer 107 (e.g., 0.4 μm to 0.9 μm thick) made of p type InGaP, which is stacked on emitter layer 106. Middle cell 12 is a joined body of an emitter layer 114 (e.g., 0.05 μm to 0.15 μm thick) made of n type InGaP, which is stacked on window layer 113, and a base layer 115 (e.g., 2.0 μm to 5.0 μm thick) made of p type GaAs, which is stacked on emitter layer 114. Bottom cell 13 is a joined body of an emitter layer 123 (e.g., 0.05 μm to 0.15 μm thick) made of n type InGaAs, which is stacked on window layer 122, and a base layer 124 (e.g., 2.0 μm to 5.0 μm thick) made of p type InGaAs, which is stacked on emitter layer 123. Each of top cell 11, middle cell 12 and bottom cell 13 has one pn junction.

A band gap increases in the order of the compound semiconductor layers constituting bottom cell 13, the compound semiconductor layers constituting middle cell 12, and the compound semiconductor layers constituting top cell 11. It is preferable that a lattice constant of window layer 122 and a lattice constant of emitter layer 123 are similar to a lattice constant of base layer 124.

Tunnel junction layer 21 has such a structure that, from the BSF layer 108 side, a p++AlGaAs layer 110 (e.g., 0.01 μm to 0.03 μm thick) and an n++InGaP layer 111 (e.g., 0.01 μm to 0.03 μm thick) are stacked in this order. Tunnel junction layer 22 has such a structure that, from the BSF layer 116 side, a p++AlGaAs layer 118 (e.g., 0.01 μm to 0.03 μm thick) and an n++InGaP layer 119 (e.g., 0.01 μm to 0.03 μm thick) are stacked in this order.

An example of a method for manufacturing the aforementioned substrate for manufacturing the compound semiconductor solar battery will be described below.

First, semiconductor substrate 100 made of n type GaAs is placed in the MOCVD device, and on this semiconductor substrate 100, third etching stop layer 101 made of n type InGaP that allows for selective etching with GaAs, second etching stop layer 102 made of n type GaAs, and first etching stop layer 103 made of n type AlAs are epitaxially grown in this order by the MOCVD method.

Next, on first etching stop layer 103 made of n type AlAs, contact layer 104 made of n type GaAs, window layer 105 made of n type AlInP, emitter layer 106 made of n type InGaP, and base layer 107 made of p type InGaP are epitaxially grown in this order by the MOCVD method. Emitter layer 106 and base layer 107 constitute top cell 11.

Next, on base layer 107 made of p type InGaP, BSF layer 108 made of p type AlInP, p+InGaP layer 109, p++AlGaAs layer 110, n++InGaP layer 111, and n+AlInP layer 112 are epitaxially grown in this order by the MOCVD method. P++AlGaAs layer 110 and n++InGaP layer 111 constitute tunnel junction layer 21.

Next, on n+AlInP layer 112, window layer 113 made of n type AlInP, emitter layer 114 made of n type InGaP, and base layer 115 made of p type GaAs are epitaxially grown in this order by the MOCVD method. Emitter layer 114 and base layer 115 constitute middle cell 12.

Next, on base layer 115 made of p type GaAs, BSF layer 116 made of p type InGaP, p+InGaP layer 117, p++AlGaAs layer 118, n++InGaP layer 119, and n+AlInP layer 120 are epitaxially grown in this order by the MOCVD method. P++AlGaAs layer 118 and n++InGaP layer 119 constitute tunnel junction layer 22.

Next, on n+AlInP layer 120, buffer layer 121 made of n type InGaP, window layer 122 made of n type InGaP, emitter layer 123 made of n type InGaAs, base layer 124 made of p type InGaAs, BSF layer 125 made of p type InGaP, and contact layer 126 made of p type InGaAs are epitaxially grown in this order by the MOCVD method. Emitter layer 123 and base layer 124 constitute bottom cell 13.

A conductivity type of each compound semiconductor layer can become n type by causing each compound semiconductor layer to contain an n type impurity such as phosphorus (P), or can become p type by causing each compound semiconductor layer to contain a p type impurity such as boron (B).

The compound semiconductor layers made of InGaP can be epitaxially grown by using a TMI (trimethylindium) gas, a TMG (trimethylgallium) gas and the PH₃ gas. The compound semiconductor layers made of GaAs can be epitaxially grown by using the AsH₃ gas and the TMG gas. The compound semiconductor layers made of AlInP can be epitaxially grown by using a TMA (trimethylaluminum) gas, the TMI gas and the PH₃ gas. The compound semiconductor layers made of AlGaAs can be epitaxially grown by using the TMA gas, the TMG gas and the AsH₃ gas. The compound semiconductor layers made of InGaAs can be epitaxially grown by using the TMI gas, the TMG gas and the AsH₃ gas. The compound semiconductor layers made of AlAs can be epitaxially grown by using the TMA gas and the AsH₃ gas.

Therefore, when first etching stop layer 103 made of n type AlAs is formed, and then, contact layer 104 made of n type GaAs is formed, the gasses in the MOCVD device are switched from TMA and AsH₃ for forming etching stop layer 103 to TMG and AsH₃ for forming contact layer 104. That is, substantially, TMA may only be changed to TMG. Therefore, it is unnecessary to do switching from the mixed gas containing the PH₃ gas to the mixed gas containing the AsH₃ gas as in the conventional art, when first etching stop layer 103 and contact layer 104 are continuously formed.

The inventors of the present invention have found that, in order to suppress mixing of the source gasses that is responsible for formation of an unintended modified layer, it is important to switch only the source gas for supplying the group III element and not switch the source gas for supplying the group V element when the etching stop layer and the contact layer are continuously formed as described above. Therefore, formation of the unintended modified layer at an interface between first etching stop layer 103 and contact layer 104 can be suppressed. Thus, as a result, the substrate for manufacturing the compound semiconductor solar battery of excellent performance can be provided.

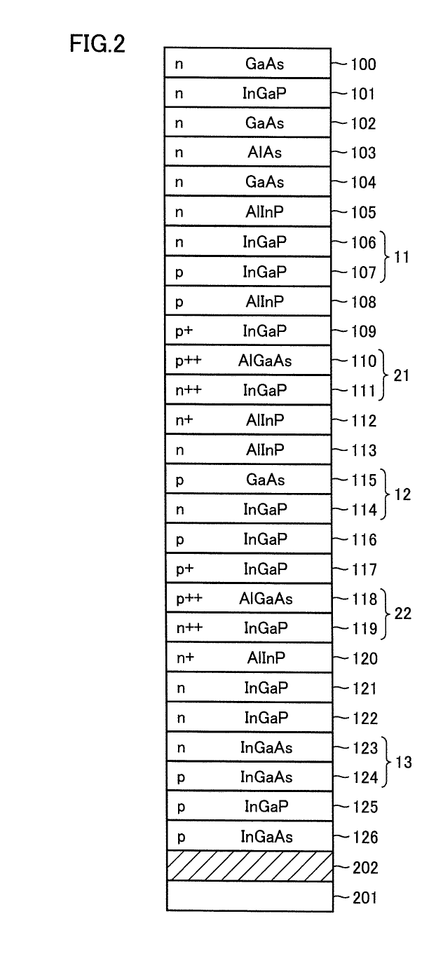

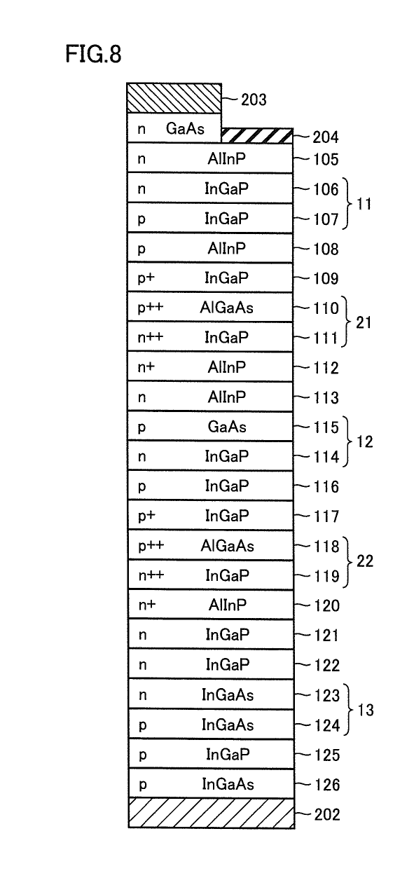

Next, an example of a method for manufacturing the compound semiconductor solar battery using the substrate for manufacturing the compound semiconductor solar battery having a structure shown in FIG. 1 will be described with reference to cross-sectional structure diagrams in FIGS. 2 to 8. Each of FIGS. 2 to 7 is a schematic cross-sectional structure diagram illustrating part of a manufacturing process of the example of the method for manufacturing the compound semiconductor solar battery using the stacked body for manufacturing the compound semiconductor solar battery shown in FIG. 1. FIG. 8 is a schematic cross-sectional structure diagram of an example of the manufactured compound semiconductor solar battery.

First, as shown in FIG. 2, a metal layer 202 formed of, for example, a stacked body including Au (e.g., 0.1 μm thick)/Ag (e.g., 3 μm thick) is, for example, vacuum-deposited on a surface of contact layer 126 made of p type InGaAs, and a support substrate 201 is attached onto a surface of this metal layer 202. A material of support substrate 201 is not particularly limited and organic materials such as polyimide can, for example, be used.

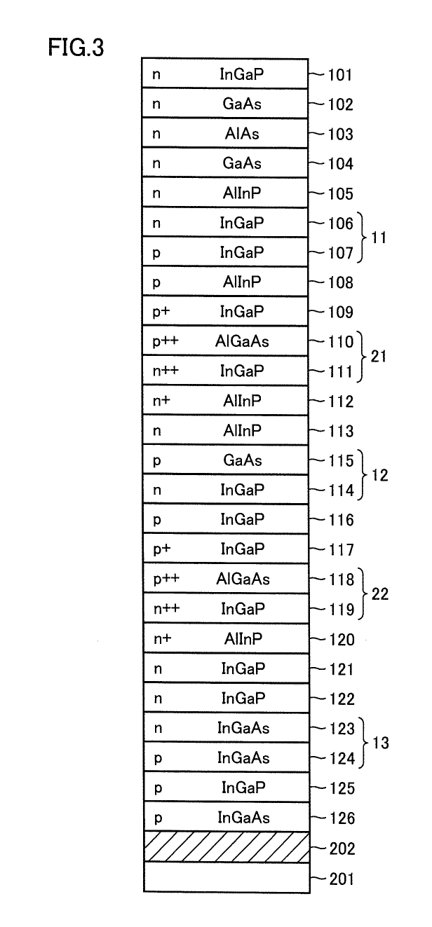

Next, as shown in FIG. 3, semiconductor substrate 100 made of n type GaAs is etchingly removed by using an alkaline aqueous solution. An aqueous solution obtained by mixing NH₄OH, H₂O₂ and H₂O at a volume ratio of 1:1:4 can, for example, be used as the alkaline aqueous solution.

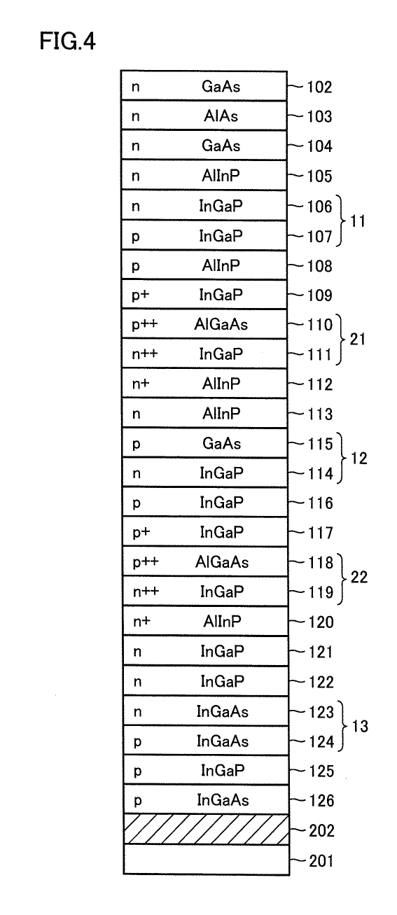

Next, as shown in FIG. 4, third etching stop layer 101 made of n type InGaP is etchingly removed by using an acid aqueous solution. An aqueous solution obtained by mixing hydrochloric acid (HCl) and H₂O at a weight ratio of 96:4 can, for example, be used as the acid aqueous solution. Etchingly removing third etching stop layer 101 made of n type InGaP by using the hydrochloric acid aqueous solution is preferable because an etching speed of second etching stop layer 102 made of n type GaAs is sufficiently lower than an etching speed of third etching stop layer 101, and thus, third etching stop layer 101 can be etched without etching second etching stop layer 102.

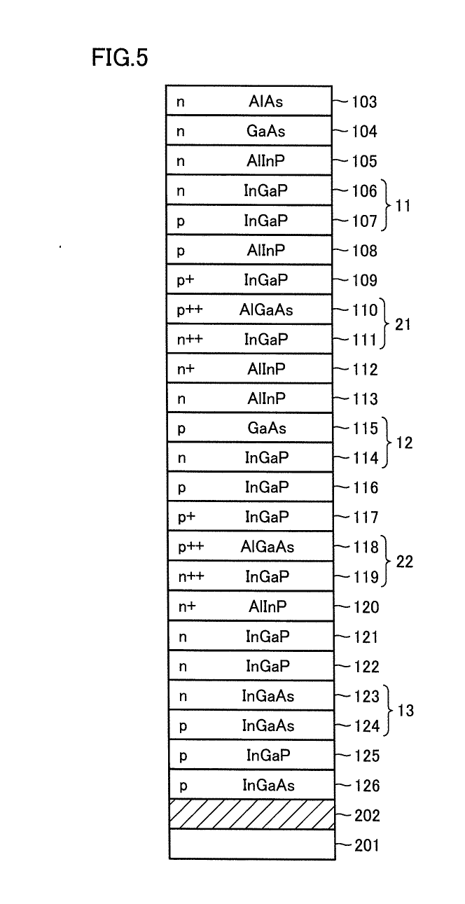

Next, as shown in FIG. 5, second etching stop layer 102 made of n type GaAs is etchingly removed by using an acid aqueous solution. A citric acid aqueous solution obtained by mixing citric acid and H₂O at a volume ratio of 1:1 can, for example, be used as the acid aqueous solution. Etchingly removing second etching stop layer 102 made of n type GaAs by using the citric acid aqueous solution is preferable because an etching speed of first etching stop layer 103 made of n type AlAs is sufficiently lower than the etching speed of second etching stop layer 102, and thus, second etching stop layer 102 can be etched without etching first etching stop layer 103.

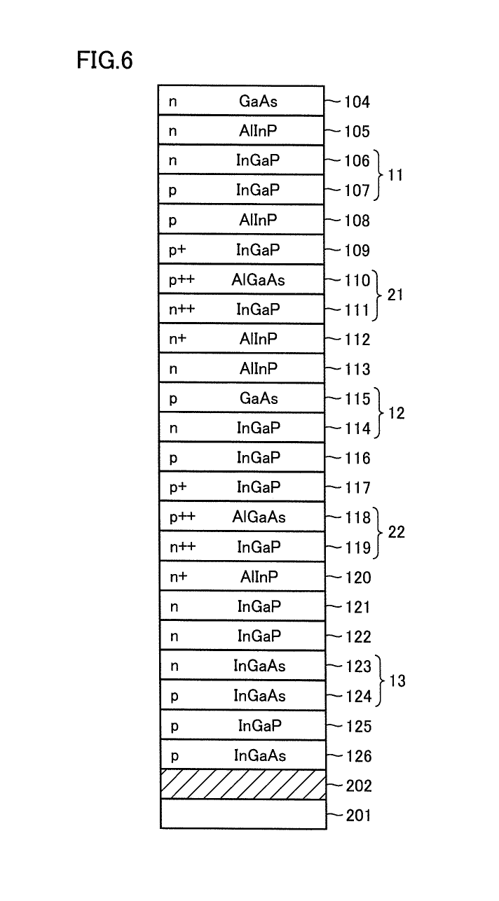

Next, as shown in FIG. 6, first etching stop layer 103 made of n type AlAs is etchingly removed by using an acid aqueous solution. 10 volume % of hydrofluoric acid (HF) aqueous solution can, for example, be used as the acid aqueous solution. Etchingly removing first etching stop layer 103 made of n type AlAs by using the hydrofluoric acid aqueous solution is preferable because an etching speed of contact layer 104 made of n type GaAs is sufficiently lower than the etching speed of first etching stop layer 103, and thus, first etching stop layer 103 can be etched without etching contact layer 104. As a result, a surface of contact layer 104 is exposed.

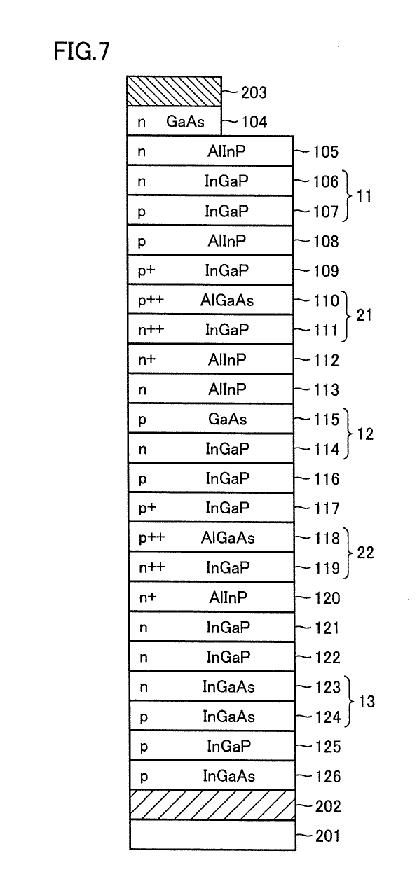

Next, as shown in FIG. 7, a resist pattern is formed by photolithography on contact layer 104 made of n type GaAs, and then, contact layer 104 is partially removed by etching with an alkaline aqueous solution. Next, an electrode layer 203 formed of a stacked body including AuGe (12%) (e.g., 0.1 μm thick)/Ni (e.g., 0.02 μm thick)/Au (e.g., 0.1 μm thick)/Ag (e.g., 5 μm thick), for example, is formed by using a vacuum deposition device.

Next, as shown in FIG. 8, an antireflection film 204 formed of a stacked body including a TiO₂ film and an Al₂O₃ film, for example, is formed on a surface of window layer 105. Next, support substrate 201 is removed.

As a result, the compound semiconductor solar battery having the structure shown in FIG. 8 with a light-receiving surface positioned opposite to a growth direction of the compound semiconductor can be obtained. In this compound semiconductor solar battery, the modified layer is not present between contact layer 104 and electrode layer 203 formed thereon, and thus, inhibition of contact between contact layer 104 and electrode layer 203 can be suppressed. Therefore, the compound semiconductor solar battery is superior in electric property to conventional compound semiconductor solar batteries.

In particular, in the present embodiment, the compound semiconductor solar battery is manufactured using the stacked body for manufacturing the compound semiconductor solar battery in which second etching stop layer 102 made of n type GaAs and third etching stop layer 101 made of n type InGaP are arranged between first etching stop layer 103 made of n type AlAs and semiconductor substrate 100 made of n type GaAs. Thus, as a result, the serial resistance in the manufactured compound semiconductor solar battery can be decreased as compared with that of the conventional compound semiconductor solar batteries. A reason for this will be described below in comparison with the technique disclosed in PTD 1 (conventional art).

Specifically, in the conventional art, the etching stop layer made of InGaP is formed on the semiconductor substrate serving as the growth substrate, and the contact layer constituting the compound semiconductor solar battery is formed to be in contact with the etching stop layer. When the etching stop layer is epitaxially grown on the semiconductor substrate, the mixed gas containing the PH₃ gas is introduced into the MOCVD device having the semiconductor substrate arranged therein. When the contact layer is epitaxially grown on the etching stop layer, the mixed gas containing the AsH₃ gas is introduced into this MOCVD device.

Therefore, in the conventional art, it is necessary to do switching from the mixed gas containing the PH₃ gas to the mixed gas containing the AsH₃ gas in the MOCVD device. At the time of this switching, however, there exists a state in which both gases are present in a mixed manner. Therefore, the unintended modified layer is formed at the interface between the etching stop layer and the contact layer.

It is difficult to etch the aforementioned modified layer with either the acid aqueous solution for etching the etching stop layer made of InGaP or the alkaline aqueous solution for etching the contact layer made of GaAs. Therefore, in the conventional art, when the electrode layer is formed on the contact layer in the subsequent step, the modified layer is present at an interface between the electrode layer and the contact layer. Presence of the modified layer inhibits contact between the contact layer and the electrode layer and the serial resistance in the compound semiconductor solar battery increases. As a result, the desired conversion efficiency cannot be obtained.

In contrast, according to the first embodiment, the modified layer is not formed between first etching stop layer 103 and contact layer 104. Therefore, contact between contact layer 104 having a desired carrier concentration and electrode layer 203 is not inhibited and both layers can be in contact with each other directly and uniformly. Thus, as a result, the serial resistance in the manufactured compound semiconductor solar battery can be decreased.

### Second Embodiment

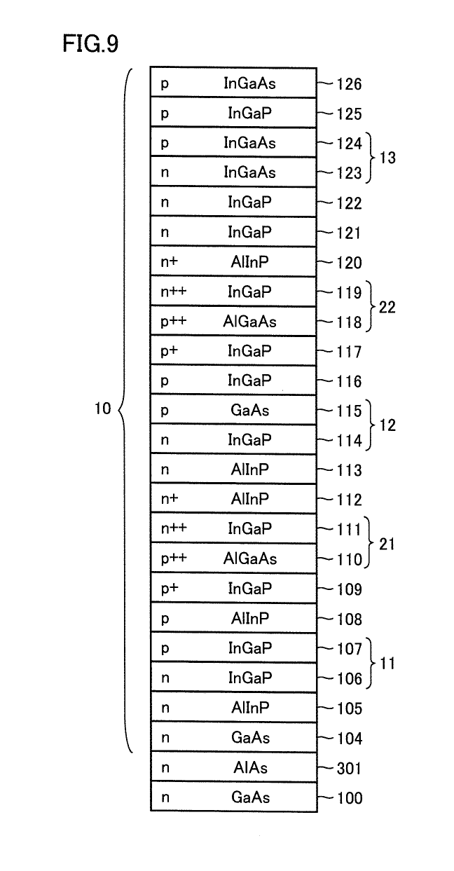

FIG. 9 is a schematic cross-sectional structure diagram of an example of a stacked body for manufacturing a compound semiconductor solar battery according to a second embodiment. This stacked body for manufacturing the compound semiconductor solar battery has a structure similar to that of the stacked body for manufacturing the compound semiconductor solar battery according to the first embodiment except that a first etching stop layer 301 (e.g., 0.01 μm to 0.1 μm thick) made of n type AlAs and semiconductor stacked body 10 are continuously arranged in this order on semiconductor substrate 100 (e.g., having a diameter of 100 mm) made of n type GaAs. Therefore, description of the structure will not be repeated.

In addition, a method for manufacturing this stacked body for manufacturing the compound semiconductor solar battery is similar to the method for manufacturing the stacked body for manufacturing the compound semiconductor solar battery according to the first embodiment except that first etching stop layer 301 made of n type AlAs that allows for selective etching with GaAs is epitaxially grown on semiconductor substrate 100 by the MOCVD method. Therefore, description of the manufacturing method will not be repeated.

In the present embodiment as well, TMA may only be changed to TMG when first etching stop layer 301 and contact layer 104 are continuously formed. Therefore, it is unnecessary to do switching from the mixed gas containing the PH₃ gas to the mixed gas containing the AsH₃ gas as in the conventional art when first etching stop layer 103 and contact layer 104 are continuously formed. Therefore, formation of the unintended modified layer at an interface between first etching stop layer 301 and contact layer 104 can be suppressed. Thus, as a result, the substrate for manufacturing the compound semiconductor solar battery of excellent performance can be provided.

Next, an example of a method for manufacturing the compound semiconductor solar battery using the substrate for manufacturing the compound semiconductor solar battery shown in FIG. 9 will be described with reference to cross-sectional structure diagrams in FIGS. 10, 11 and 6 to 8. Each of FIGS. 10, 11, 6 and 7 is a schematic cross-sectional structure diagram illustrating part of a manufacturing process of the example of the method for manufacturing the compound semiconductor solar battery using the stacked body for manufacturing the compound semiconductor solar battery shown in FIG. 9, and FIG. 8 is a schematic cross-sectional structure diagram of an example of the manufactured compound semiconductor solar battery.

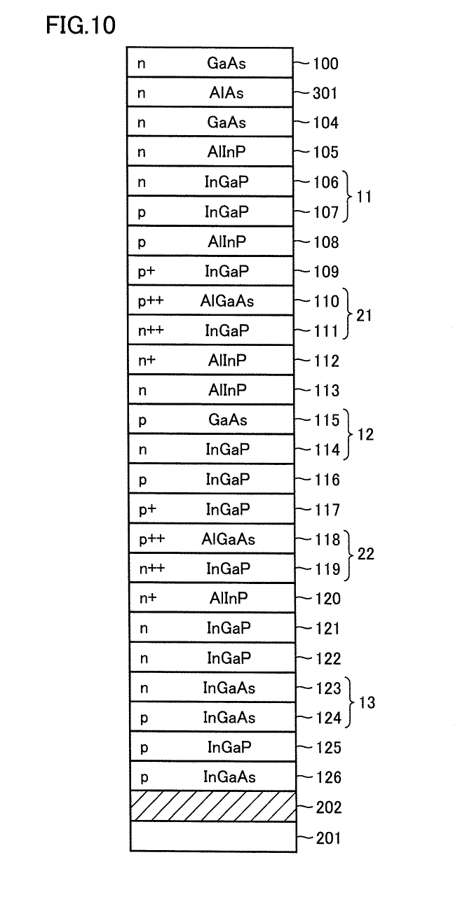

First, as shown in FIG. 10, metal layer 202 is formed on the surface of contact layer 126 made of p type InGaAs, similarly to the first embodiment, and support substrate 201 is attached onto the surface of this metal layer 202.

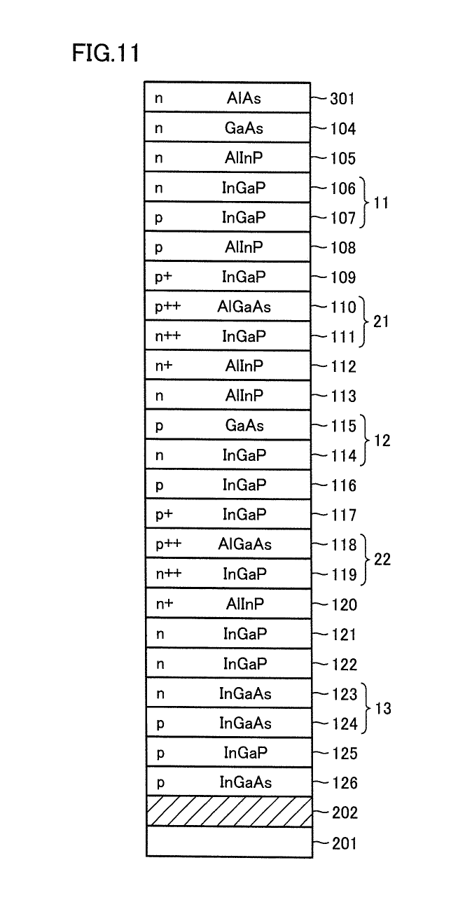

Next, as shown in FIG. 11, semiconductor substrate 100 made of n type GaAs is etchingly removed by using an acid aqueous solution. A citric acid aqueous solution obtained by mixing citric acid and H₂O at a volume ratio of 1:1 can, for example, be used as the acid aqueous solution.

Next, as shown in FIG. 6, first etching stop layer 301 made of n type AlAs is etchingly removed by using an acid aqueous solution. Similarly to the first embodiment, 10 volume % of hydrofluoric acid aqueous solution can, for example, be used as the acid aqueous solution.

In the first embodiment, semiconductor substrate 100 is etchingly removed by using the alkaline aqueous solution. However, if semiconductor substrate 100 is etchingly removed by using the alkaline aqueous solution in the second embodiment, first etching stop layer 301 made of AlAs and contact layer 104 made of GaAs are also etched when semiconductor substrate 100 is removed. That is, if semiconductor substrate 100 is etchingly removed by using the alkaline aqueous solution in the second embodiment, first etching stop layer 301 does not function as an etching stop layer.

Therefore, in the second embodiment, semiconductor substrate 100 is etchingly removed by using the citric acid aqueous solution. Since first etching stop layer 301 made of AlAs is not etchingly removed by the citric acid aqueous solution, first etching stop layer 301 can function as an etching stop layer.

Next, similarly to the first embodiment, as shown in FIG. 7, electrode layer 203 is formed on the surface of contact layer 104, and further, as shown in FIG. 8, antireflection film 204 is formed on the surface of window layer 105, and support substrate 201 is removed.

As a result, the compound semiconductor solar battery having the structure shown in FIG. 8 with a light-receiving surface positioned opposite to a growth direction of the compound semiconductor can be obtained. In this compound semiconductor solar battery, the modified layer is not present between contact layer 104 and electrode layer 203 formed thereon, and thus, inhibition of contact between contact layer 104 and electrode layer 203 can be suppressed. Thus, as a result, the compound semiconductor solar battery is superior in electric property to conventional compound semiconductor solar batteries.

In particular, in the second embodiment, the compound semiconductor solar battery can be manufactured by using the stacked body for manufacturing the compound semiconductor solar battery that has the one-tier etching stop layer. Therefore, the number of the etching removal steps can be reduced as compared with the first embodiment, and thus, the manufacturing process can be simplified.

In addition, in the second embodiment, first etching stop layer 301 may be etched from a side surface of first etching stop layer 301 by the epitaxial lift (ELO) method by using the acid aqueous solution (e.g., 10 mass % of hydrofluoric acid aqueous solution). In this case, first etching stop layer 301 and semiconductor substrate 100 can be removed simultaneously and the manufacturing process can be further simplified.

The second embodiment is similar to the first embodiment except for the above description, and thus, the description thereof will not be repeated.

### EXAMPLES

### Example 1

<<Fabrication of Stacked Body for Manufacturing Compound Semiconductor Solar Battery>>

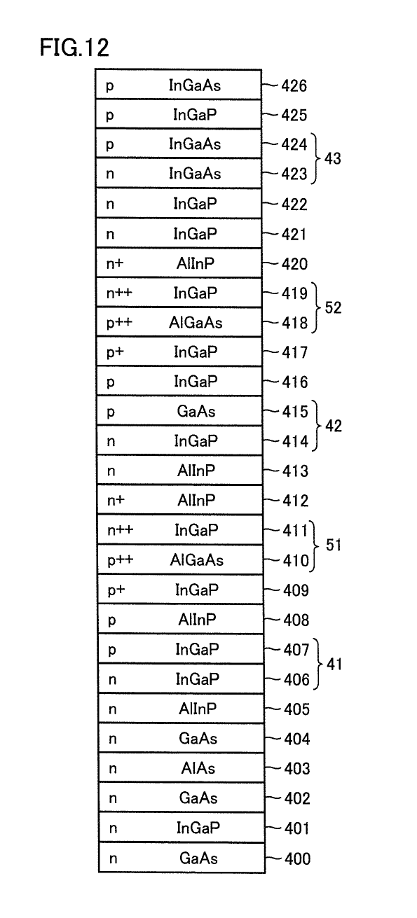

A stacked body for manufacturing a compound semiconductor solar battery shown in FIG. 12 was fabricated.

Specifically, first, as shown in FIG. 12, a semiconductor substrate 400 made of n type GaAs and having a diameter of 100 mm was placed in an MOCVD device, and on this semiconductor substrate 400, a third etching stop layer 401 made of n type InGaP and having a thickness of 150 nm, a second etching stop layer 402 made of n type GaAs and having a thickness of 500 nm, and a first etching stop layer 403 made of n type Al_{0.5}As_{0.5} and having a thickness of 30 nm were epitaxially grown in this order by the MOCVD method.

Next, on first etching stop layer 403, a contact layer 404 made of n type GaAs and having a thickness of 500 nm, a window layer 405 made of n type AlInP and having a thickness of 50 nm, an emitter layer 406 made of n type In_{0.48}Ga_{0.52}P and having a thickness of 50 nm, a base layer 407 made of p type In_{0.48}Ga_{0.52}P and having a thickness of 650 nm, and a BSF layer 408 made of p type AlInP and having a thickness of 50 nm were epitaxially grown in this order by the MOCVD method. Emitter layer 406 and base layer 407 constituted top cell 41.

Next, on BSF layer 408, a p+ In_{0.48}Ga_{0.52}P layer 409 having a thickness of 50 nm, a p++AlGaAs layer 410 having a thickness of 20 nm, an n++ In_{0.48}Ga_{0.52}P layer 411 having a thickness of 20 nm, and an n+AlInP layer 412 having a thickness of 50 nm were epitaxially grown in this order by the MOCVD method. P++AlGaAs layer 410 and n++ In_{0.48}Ga_{0.52}P layer 411 constituted tunnel junction layer 51.

Next, on n+AlInP layer 412, a window layer 413 made of n type AlInP and having a thickness of 100 nm, an emitter layer 414 made of n type In_{0.48}Ga_{0.52}P and having a thickness of 100 nm, a base layer 415 made of p type GaAs and having a thickness of 3000 nm, and a BSF layer 416 made of p type In_{0.48}Ga_{0.52}P and having a thickness of 100 nm were epitaxially grown in this order by the MOCVD method. Emitter layer 414 and base layer 415 constituted middle cell 42.

Next, on BSF layer 416, a p+ In_{0.48}Ga_{0.52}P layer 417 having a thickness of 50 nm, a p++AlGaAs layer 418 having a thickness of 20 nm, an n++InGaP layer 419 having a thickness of 20 nm, and an n+AlInP layer 420 having a thickness of 50 nm were epitaxially grown in this order by the MOCVD method. P++AlGaAs layer 418 and n++ In_{0.48}Ga_{0.52}P layer 419 constituted tunnel junction layer 52.

Next, on n+AlInP layer 420, a buffer layer 421 made of n type InₓGa₁₋ₓP (x=0.48 to 0.82) and having a thickness of 3000 nm, a window layer 422 made of n type InGaP and having a thickness of 100 nm, an emitter layer 423 made of n type InGaAs and having a thickness of 100 nm, a base layer 424 made of p type InGaAs and having a thickness of 3000 nm, a BSF layer 425 made of p type InGaP and having a thickness of 100 nm, and a contact layer 426 made of p type InGaAs and having a thickness of 400 nm were epitaxially grown in this order by the MOCVD method. Emitter layer 423 and base layer 424 constituted bottom cell 43.

As a result, the stacked body for manufacturing the compound semiconductor solar battery shown in FIG. 12 was fabricated. A conductivity type of each compound semiconductor layer became n type by causing each compound semiconductor layer to contain phosphorus (P), or became p type by causing each compound semiconductor layer to contain boron (B).

<<Fabrication of Compound Semiconductor Solar Battery>>

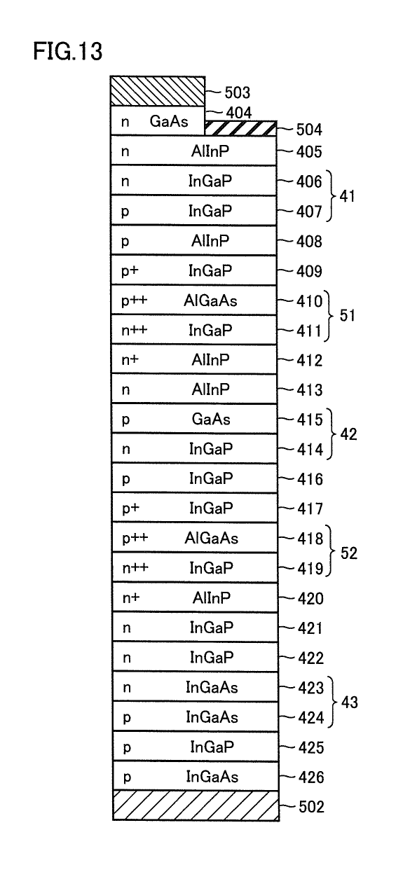

Next, the compound semiconductor solar battery shown in FIG. 13 was fabricated using the stacked body for manufacturing the compound semiconductor solar battery shown in FIG. 12.

Specifically, first, a metal layer 502 (refer to FIG. 13) formed of a stacked body including Au (0.1 μm thick)/Ag (3 μm thick) was vacuum-deposited on a surface of contact layer 426 made of p type InGaAs in the stacked body for manufacturing the compound semiconductor solar battery shown in FIG. 12, and a support substrate made of polyimide was attached onto a surface of this metal layer 502.

Next, semiconductor substrate 400 made of n type GaAs was etchingly removed by using an alkaline aqueous solution obtained by mixing NH₄OH, H₂O₂ and H₂O at a volume ratio of 1:1:4, and third etching stop layer 401 made of n type InGaP was etchingly removed by using a 100% hydrochloric acid aqueous solution. Furthermore, second etching stop layer 402 made of n type GaAs was etchingly removed by using a citric acid aqueous solution obtained by mixing citric acid and H₂O at a volume ratio of 1:1, and then, first etching stop layer 403 made of n type AlAs was etchingly removed by using a 10 volume % of hydrofluoric acid aqueous solution.

Next, a resist pattern was formed by photolithography on contact layer 404 made of n type GaAs, and then, contact layer 404 was partially removed by etching with an alkaline aqueous solution and a resist pattern was again formed by photolithography on a surface of remaining contact layer 404. Then, an electrode layer 503 (refer to FIG. 13) formed of a stacked body including AuGe (12%) (0.1 μm thick)/Ni (0.02 μm thick)/Au (0.1 μm thick)/Ag (5 μm thick) was formed by using the vacuum deposition device.

Next, an antireflection film 504 formed of a stacked body including a TiO₂ film and an Al₂O₃ film was formed on window layer 405 made of n type AlInP by the EB deposition method. Furthermore, the support substrate was removed.

As a result, the compound semiconductor solar battery having the structure shown in FIG. 13 with a light-receiving surface positioned opposite to a growth direction of the compound semiconductor was fabricated.

### Comparative Example 1

<<Fabrication of Stacked Body for Manufacturing Compound Semiconductor Solar Battery>>

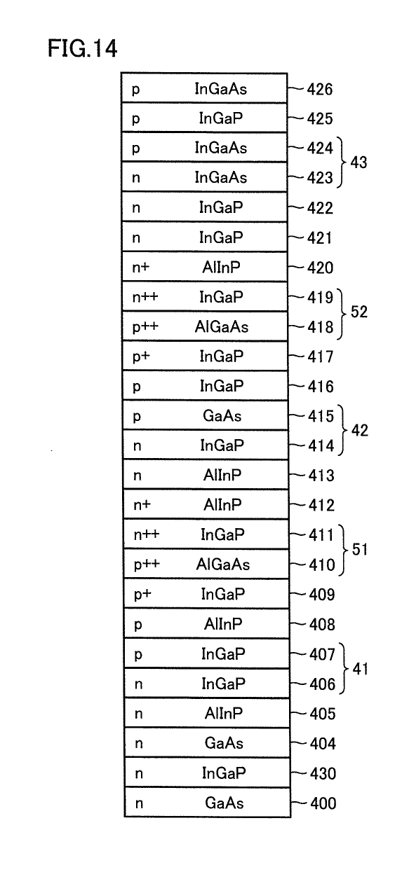

A stacked body for manufacturing a compound semiconductor solar battery shown in FIG. 14 was fabricated.

Specifically, first, as shown in FIG. 14, semiconductor substrate 400 made of n type GaAs and having a diameter of 100 mm was placed in the MOCVD device, and on this semiconductor substrate 400, an etching stop layer 430 made of n type In_{0.48}Ga_{0.52}P and having a thickness of 150 nm was epitaxially grown by the MOCVD method. The structure of a semiconductor stacked body formed on etching stop layer 430 and a method for fabricating the same were similar to those in Example 1, and thus, description thereof will not be repeated.

<<Fabrication of Compound Semiconductor Solar Battery>>

Next, the compound semiconductor solar battery shown in FIG. 13 was formed using the stacked body for manufacturing the compound semiconductor solar battery shown in FIG. 14.

Specifically, first, metal layer 502 formed of a stacked body including Au (0.1 thick)/Ag (3 μm thick) was vacuum-deposited on the surface of contact layer 426 made of p type InGaAs in the stacked body for manufacturing the compound semiconductor solar battery shown in FIG. 14, and the support substrate made of polyimide was attached onto the surface of this metal layer 502.

Next, semiconductor substrate 400 made of n type GaAs was etchingly removed by using an alkaline aqueous solution obtained by mixing NH₄OH, H₂O₂ and H₂O at a volume ratio of 1:1:4, and etching stop layer 430 made of n type In_{0.48}Ga_{0.52}P was etchingly removed by using an aqueous solution obtained by mixing hydrochloric acid (HCl) and H₂O at a weight ratio of 96:4.

Next, on contact layer 404 made of n type GaAs, electrode layer 503 (refer to FIG. 13) formed of a stacked body including AuGe (12%) (0.1 μm thick)/Ni (0.02 μm thick)/Au (0.1 μm thick)/Ag (5 μm thick) as well as antireflection film 504 (refer to FIG. 13) were formed by the method similar to that in Example 1, and further, the support substrate was removed.

As a result, the compound semiconductor solar battery having the structure shown in FIG. 13 with a light-receiving surface positioned opposite to a growth direction of the compound semiconductor was fabricated.

<Evaluation>

Current-voltage characteristics of each of the compound semiconductor solar battery fabricated in Example 1 and the compound semiconductor solar battery fabricated in Comparative Example 1 were measured. The current-voltage characteristics were measured using solar simulator light (under the environment of AM 1.5, an energy density of 100 mW/cm², and 25° C.).

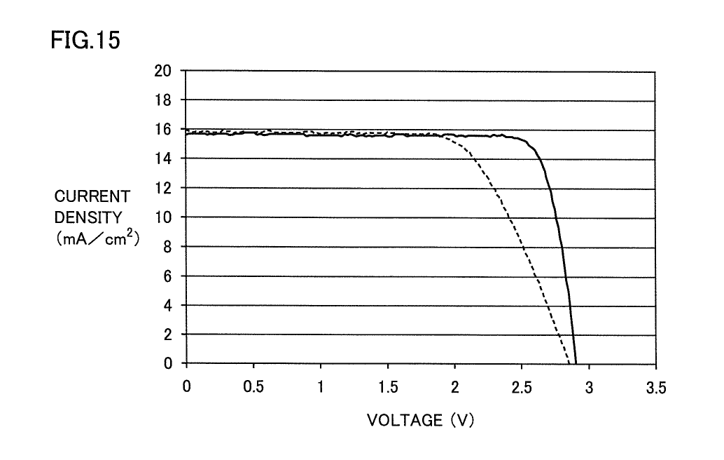

FIG. 15 is a graph showing the current-voltage characteristics of the compound semiconductor solar battery in each of Example 1 and Comparative Example 1. In the graph, the solid line represents the current-voltage characteristics of the compound semiconductor solar battery in Example 1, and the dotted line represents the current-voltage characteristics of the compound semiconductor solar battery in Comparative Example 1.

As shown in FIG. 15, it has turned out that there is no large difference in short-circuit current (Isc) and open-circuit voltage (Voc) between the compound semiconductor solar battery in Example 1 and the compound semiconductor solar battery in Comparative Example 1, while the compound semiconductor solar battery in Example 1 is superior in fill factor (F.F) to the compound semiconductor solar battery in Comparative Example 1. This is considered to be because the compound semiconductor solar battery in Example 1 is superior in contact between contact layer 404 and metal layer 502 to the compound semiconductor solar battery in Comparative Example 1. This is also considered to be because the serial resistance of the solar battery decreases by using the three-tier etching stop layer in Example 1.

It should be understood that the embodiments and the examples disclosed herein are illustrative and not limitative in any respect. The scope of the present invention is defined by the terms of the claims, rather than the description above, and is intended to include any modifications within the scope and meaning equivalent to the terms of the claims.

### INDUSTRIAL APPLICABILITY

The present invention can be used in a stacked body for manufacturing a compound semiconductor solar battery, a compound semiconductor solar battery, and a method for manufacturing a compound semiconductor solar battery.

### REFERENCE SIGNS LIST

10 semiconductor stacked body; 11, 41 top cell; 12, 42 middle cell; 13, 43 bottom cell; 21, 22, 51, 52 tunnel junction layer; 100, 400 semiconductor substrate; 101, 401 third etching stop layer; 102, 402 second etching stop layer; 103, 403 first etching stop layer; 430 etching stop layer; 104, 126, 404, 426 contact layer; 105, 113, 122, 405, 413, 422 window layer; 106, 114, 123, 406, 414, 423 emitter layer; 107, 115, 124, 407, 415, 424 base layer; 108, 116, 125, 408, 416, 425 BSF layer; 109, 117, 409, 417 p+ InGaP layer; 110, 118, 410, 418 p++AlGaAs layer; 111, 119, 411, 419 n++ InGaP layer; 112, 120, 412, 420 n+ AlInP layer; 201 support substrate; 202, 502 metal layer; 203, 503 electrode layer; 204, 504 antireflection film.

1. (canceled)

2. A stacked body for manufacturing a compound semiconductor solar battery, wherein
a first etching stop layer and a semiconductor stacked body including at least one pn junction are arranged in this order on a semiconductor substrate,
said semiconductor stacked body has a contact layer at a position in contact with said first etching stop layer,
each of said first etching stop layer and said contact layer contains a group V element, and
said group V element contained in said first etching stop layer and said group V element contained in said contact layer are of the same type.

3. The stacked body for manufacturing a compound semiconductor solar battery according claim 2, wherein
said first etching stop layer and said semiconductor stacked body are epitaxially grown layers.

4. The stacked body for manufacturing a compound semiconductor solar battery according to claim 2, wherein
said first etching stop layer is an AlAs layer.

5. The stacked body for manufacturing a compound semiconductor solar battery according to claim 2, wherein
between said semiconductor substrate and said first etching stop layer a second etching stop layer and a third etching stop layer are arranged in this order from said first etching stop layer side.

6. The stacked body for manufacturing a compound semiconductor solar battery according to claim 5, wherein
said second etching stop layer and said third etching stop layer are epitaxially grown layers.

7. The stacked body for manufacturing a compound semiconductor solar battery according to claim 5, wherein
said second etching stop layer is a GaAs layer and said third etching stop layer is an InGaP layer.

8. The stacked body for manufacturing a compound semiconductor solar battery according to claim 2, wherein
said contact layer is a GaAs layer.

9. A compound semiconductor solar battery manufactured using the stacked body for manufacturing a compound semiconductor solar battery as recited in claim 2, the compound semiconductor solar battery comprising said semiconductor stacked body.

10. The compound semiconductor solar battery according to claim 9, formed by etching said first etching stop layer that is in contact with said contact layer of said semiconductor stacked body.

11. (canceled)

12. A method for manufacturing a compound semiconductor solar battery, comprising the steps of:
forming a first etching stop layer on a semiconductor substrate;
forming, on said first etching stop layer a semiconductor stacked body including at least one pn junction;
arranging a support substrate on a compound semiconductor layer formed at a position farthest from said first etching stop layer of said semiconductor stacked body; and
etching said first etching stop layer, wherein
said step of forming a semiconductor stacked body includes the step of forming a contact layer at a position in contact with said first etching stop layer;
each of said first etching stop layer and said contact layer contains a group V element, and
said group V element contained in said first etching stop layer and said group V element contained in said contact layer are of the same type.

13. The method for manufacturing a compound semiconductor solar battery according to claim 12, wherein
said step of forming a first etching stop layer includes the steps of: forming a third etching stop layer on said semiconductor substrate; forming a second etching stop layer on said third etching stop layer; and forming said first etching stop layer on said second etching stop layer.

14. The method for manufacturing a compound semiconductor solar battery according to claim 13, wherein
the step of etching said third etching stop layer and the step of etching said second etching stop layer are included before the step of etching said first etching stop layer.

15. The method for manufacturing a compound semiconductor solar battery according to claim 14, wherein
at least any one of acids selected from the group of hydrofluoric acid, citric acid and hydrochloric acid is used in at least one of the step of etching said first etching stop layer, the step of etching said second etching stop layer and the step of etching said third etching stop layer.
